(19) United States
(12) Patent Application Publication
(10) Pub. No.: US 2017/0162418 A1
(43) Pub. Date: Jun. 8, 2017

(54) COMPONENT CARRIER TAPE WITH UV RADIATION CURABLE ADHESIVE

(71) Applicant: 3M INNOVATIVE PROPERTIES COMPANY, St. Paul, MN (US)

(72) Inventors: Bing Huang, Shanghai (CN); Chu Ouyang, Shanghai (CN); Wei Xiang Zhang, Shanghai (CN); Shijun Shen, Shanghai (CN); Hengyuan Zhou, Shanghai (CN); Yan Jin, Shanghai (CN); Xuzhi Cheng, Shanghai (CN)

(21) Appl. No.: 15/436,962

(22) Filed: Feb. 20, 2017

Related U.S. Application Data
(62) Division of application No. 14/415,624, filed on Feb. 2, 2015, now abandoned.

(51) Int. Cl. H01L 21/683; H01L 21/67; B65D 73/02

(52) U.S. Cl. CPC H01L 21/6835; B65D 73/02; H01L 21/67132; B65D 2313/10; H01L 2221/68354; H01L 2221/68386

(57) ABSTRACT

A carrier tape for transporting a plurality of components includes a flexible substrate extending along a longitudinal axis of the carrier tape, a plurality of pockets formed in the substrate and spaced apart along the longitudinal axis of the carrier tape, and an adhesive layer. Each pocket includes a bottom wall and a side wall extending from the bottom wall to a top surface of the flexible substrate. The adhesive layer is disposed on the bottom wall of each pocket in the plurality of pockets, such that when a component is placed in a pocket in the plurality of pockets, the adhesive layer in the pocket permanently bonds to the component, and such that when the adhesive is exposed to UV radiation the adhesive bond strength is sufficiently reduced so that the component can be removed from the pocket.

### TECHNICAL FIELD

The present disclosure relates to storage and transport carrier tapes for small electronic components. More particularly, it is directed to carrier tapes that allow easy placement and release of small electronic components using an ultraviolet (UV) radiation curable adhesive.

### BACKGROUND

As the size of small electronic components shrinks, methods for packing these components for automated handling become more challenging. Automated factories cannot function efficiently unless the feedstock components are pre-packed in a uniform, industry standard manner. Components, such as, e.g., integrated circuit (IC) chips or surface mount technology (SMT) components, packed in a tape and reel format for low cost, high volume, pick and place assembly in automated factories are widely used in the electronics industry.

Pick and place operations for IC chips typically involve picking individual IC chips at the dicing station, placing the IC chips individually in designated sites on the carrier tape, moving the carrier tape to another pick station, picking the IC chips from the carrier tape, and placing the IC chips on a printed circuit board (PCB) or other substrate. Pick and place operations for SMT components involve picking packaged SMT components at a packing station, placing the SMT components on a carrier tape, conveying the carrier tape to an assembly station, picking the SMT components from the carrier tape, and placing the SMT components on a PCB or other substrate.

Carrier tapes are used in several forms. A widely used carrier tape has individual pockets or cavities for containing the components. A pick and place machine picks the components individually and places them in the carrier tape pockets. The carrier tapes may be reeled for storage, or for transport to the next processing station. The tapes are unreeled at the next processing station and the components are individually picked and placed again. Since the components are confined loosely in the carrier tape pockets, a cover tape is used to enclose the pockets. The cover tape is applied after the pockets are filled, and later peeled back to allow the next pick and place operation.

Another type of carrier tape is adhesive-backed carrier tape. With this type of carrier tape, the components are retained within virtual boundary compartments, and held therein, exactly as placed, by a pressure-sensitive adhesive tape. The adhesive tape is affixed to the backside of the carrier tape plastic frame. An advantage of the adhesive-backed carrier tape is that repeatable positioning of the components at the pick point can be achieved with high precision, e.g. within 10 microns. Because each components is retained by the adhesive in the exact position as placed, when a given compartment reaches the pick station, the pick tool knows precisely where the component is and how the component is oriented. This allows the pick to be made “blind”, and eliminates the need for expensive tools to “find” the components on the carrier tape. A carrier tape conveyor apparatus using adhesive-backed carrier tape is typically provided with mechanical means for aiding in releasing the component from the adhesive on the carrier tape. The mechanical means may be an ejector pin or rod that bears on the bottom of the component and, while the pick head is engaging the component, urges the component away from the tape. To accommodate the ejector pin, the adhesive-backed carrier tape is formed as two rails with a continuous opening traversing the center of the tape.

While these types of carrier tape designs are effective, and have been successful in practice, improvements are sought.

### SUMMARY

In at least one aspect, the present invention provides a carrier tape for transporting a plurality of components. The carrier tape includes a flexible substrate extending along a longitudinal axis of the carrier tape, a plurality of pockets formed in the substrate and spaced apart along the longitudinal axis of the carrier tape, and an adhesive layer. Each pocket includes a bottom wall and a side wall extending from the bottom wall to a top surface of the flexible substrate. The adhesive layer is disposed on the bottom wall of each pocket in the plurality of pockets, such that when a component is placed in a pocket in the plurality of pockets, the adhesive layer in the pocket permanently bonds to the component, and such that when the adhesive is exposed to UV radiation the adhesive bond strength is sufficiently reduced so that the component can be removed from the pocket.

In at least one aspect, the present invention provides a carrier tape for transporting a plurality of components. The carrier tape includes a flexible substrate extending along a longitudinal axis of the carrier tape and a continuous component holding layer disposed on the flexible substrate. The continuous component holding layer includes an adhesive first portion and a non-adhesive second portion. The adhesive first portion is for securing a component to the flexible substrate by adhesively bonding to the component. The adhesive first portion has a first perimeter. The non-adhesive second portion has a second perimeter partially coinciding with the first perimeter.

In at least one aspect, the present invention provides a cover tape for use with a carrier tape for transporting a plurality of components. The cover tape includes a flexible substrate extending along a longitudinal axis of the cover tape and an adhesive layer disposed on a surface of the flexible substrate. The adhesive layer is disposed on a surface of the flexible substrate such that when the cover tape is applied to a carrier tape that includes a component placed in a pocket of the carrier tape, the adhesive layer permanently bonds to the carrier tape to permanently seal the component in the pocket, and such that when the adhesive is exposed to UV radiation the adhesive bond strength is sufficiently reduced so that the cover tape can be removed from the carrier tape and the component can be removed from the pocket.

The above summary of the present invention is not intended to describe each disclosed embodiment or every implementation of the present invention. The Figures and detailed description that follow below more particularly exemplify illustrative embodiments.

### BRIEF DESCRIPTION OF THE DRAWINGS

FIG. 1A is a perspective view of an exemplary embodiment of a component carrier tape according to an aspect of the present invention.

FIG. 1B is a cross-sectional view of the component carrier tape of FIG. 1A.

FIG. 2A is a perspective view of another exemplary embodiment of a component carrier tape according to an aspect of the present invention.

FIG. 2B is a cross-sectional view of the component carrier tape of FIG. 2A.

FIG. 3A is a perspective view of another exemplary embodiment of a component carrier tape according to an aspect of the present invention.

FIG. 3B is a cross-sectional view of the component carrier tape of FIG. 3A.

FIG. 4A is a perspective view of another exemplary embodiment of a component carrier tape according to an aspect of the present invention.

FIG. 4B is a cross-sectional view of the component carrier tape of FIG. 4A.

FIG. 5A is a perspective view of an exemplary embodiment of a component carrier tape and cover tape according to an aspect of the present invention.

FIG. 5B is a cross-sectional view of the component carrier tape and cover tape of FIG. 5A.

### DETAILED DESCRIPTION

In the following detailed description of the preferred embodiments, reference is made to the accompanying drawings that form a part hereof. The accompanying drawings show, by way of illustration, specific embodiments in which the invention may be practiced. It is to be understood that other embodiments may be utilized, and structural or logical changes may be made without departing from the scope of the present invention. The following detailed description, therefore, is not to be taken in a limiting sense, and the scope of the invention is defined by the appended claims.

In the illustrated embodiments, directional representations, i.e., up, down, left, right, front, rear and the like, used for explaining the structure and movement of the various elements of the present application, are relative. These representations are appropriate when the elements are in the position shown in the Figures. If the description of the position of the elements changes, however, it is assumed that these representations are to be changed accordingly.

The term “component” is used herein to describe any suitable type of component stored and transported using carrier tapes according to aspects of the present invention. Examples of such components include IC chips, discrete components such as, e.g., resistors, capacitors, inductors, and combinations thereof, and photonic devices such as, e.g., optical integrated circuits, photodiodes, laser chips, micro-machined devices (MEMS), and micro-mirrors.

The term “carrier tape assembly” is used herein to describe an assembly of a component carrier tape and at least one component. The component carrier tape is used to transport and store the component. In some embodiments, a cover tape or film may be used to seal the component within a pocket of the carrier tape.

Carrier tapes and cover tapes according to aspects of the present invention are particularly advantageous for protecting components during transportation and delivery thereof to, e.g., robotic placement equipment. These carrier tapes and cover tapes may be used to transport components from a component manufacturer to a different manufacturer that removes the components from the carrier tape and assembles the components into new products. Carrier tapes are commonly used in conjunction with automated assembly equipment, where an advancement mechanism automatically advances the carrier tape so that robotic placement equipment can sequentially remove components from the carrier tape and place the components in another location, such as a specific position and orientation on a circuit board.

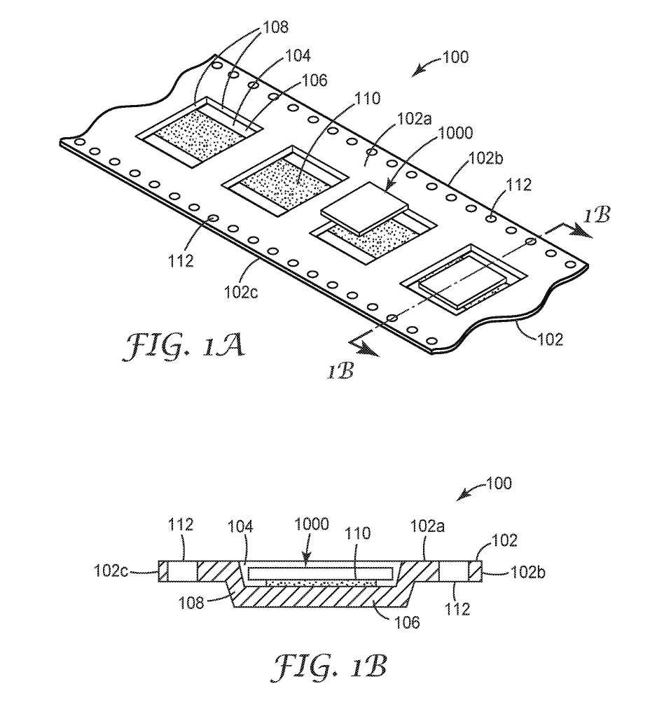

Referring now to the Figures, FIGS. 1A-1B illustrate an exemplary embodiment of a component carrier tape according to an aspect of the present invention. Carrier tape 100 is suitable for transporting a plurality of components 1000. Although carrier tape 100 is particularly suitable for use in automated processes, the carrier tape may be used in a semi-automated process where the loaded carrier tape is advanced by automated equipment. An operator, rather than a robot, then removes components from the carrier tape. It is also contemplated that the carrier tape be used in a completely manual system, where the loaded carrier tape is not used in conjunction with any type of automated equipment. Rather, the operator manually removes a component from the carrier tape then manually advances the carrier tape so that the next component may be removed. Carrier tape 100 includes a flexible substrate 102 extending along a longitudinal axis of carrier tape 100. A plurality of pockets 104 is formed in flexible substrate 102. Pockets 104 are spaced apart along the longitudinal axis of carrier tape 100. Each pocket 104 includes a bottom wall 106 and four side walls 108 extending from bottom wall 106 to a top surface 102a of flexible substrate 102. In the embodiment illustrated in FIGS. 1A-1B, each side wall 108 is formed generally at a right angle with respect to each adjacent wall. Side walls 108 adjoin and extend downwardly from top surface 102a of flexible substrate 102 and adjoin bottom wall 106 to form pocket 104. In at least one aspect, bottom wall 106 is generally planar and is parallel to top surface 102a of flexible substrate 102.

In general, pockets 104 are designed to accommodate the size and shape of the components that they are intended to receive. Although not specifically illustrated, pockets 104 may have more or fewer side walls 108 than the four side walls 108 that are illustrated in FIG. 1A. In general, each pocket 104 includes at least one side wall 108 that adjoins and extends downwardly from top surface 102a of flexible substrate 102 of carrier tape 100, and a bottom wall 106 that adjoins side wall 108 to form pocket 104. Thus, pockets 104 may be circular, oval, triangular, pentagonal, or have other suitable shapes in outline. As illustrated in FIG. 1B, each side wall 108 may also be formed with a slight draft, e.g., a 2° to 12° slant toward or away from the center of the pocket, in order to facilitate insertion of the component, and to assist in releasing the pocket from a mold or forming die during fabrication of the carrier tape. The depth of pocket 104 may also vary depending on the component that the pocket is intended to receive. In addition, the interior of pocket 104 may be formed with ledges, ribs, pedestals, bars, tabs, and other suitable structural features to better accommodate or support a particular type of component. Although FIGS. 1A-1B illustrates a single row of pockets 104, two or more rows of aligned pockets may also be formed along the longitudinal axis of the carrier tape, e.g., to facilitate the simultaneous delivery of multiple components.

Carrier tape 100 further includes an adhesive layer 110 disposed on bottom wall 106 of each pocket 104 in the plurality of pockets. Adhesive layer 110 is disposed on bottom wall 106 such that when a component 1000 is placed in a pocket 104 in the plurality of pockets, adhesive layer 110 in the pocket permanently bonds to the component. This means that adhesive layer 110 in the pocket bonds to the component such that the component cannot be removed from the pocket without damage to the component, the pocket, or both. Advantageously, this permanent bond facilitates secure storage and transportation of components by the carrier tape. In at least one aspect, this permanent bond eliminates the need for a cover tape used to seal the components in the pockets and the associated sealing process, which significantly reduces the overall cost of the component storage and transportation.

In addition, adhesive layer 110 is disposed on bottom wall 106 such that when the adhesive is exposed to UV radiation the adhesive bond strength is sufficiently reduced so that the component can be removed from the pocket. Advantageously, exposure of the adhesive to UV radiation allows the component to be quickly and easily removed from the pocket, e.g., by robotic placement equipment, without the presence of adhesive residue on the component. In at least one aspect, this method eliminates need for removal of a cover tape used to seal the components in the pockets and the associated cover tape removal equipment, which increases the speed of component pickup and placement. In at least one aspect, elimination of the cover tape removal process also reduces vibrations to the carrier tape during component pickup and placement, which increases the effectiveness (rate) of component pickup and placement.

In at least one aspect, when the adhesive is exposed to UV radiation the adhesive bond strength is reduced to zero. In at least one aspect, when the adhesive is exposed to UV radiation the adhesive bond strength is sufficiently reduced so that the component can be removed without damage to the component or the carrier tape. In at least one aspect, sufficient bond strength remains to facilitate transportation of the component, e.g., from the UV radiation location to the pick and place location in the SMT process, without displacement of the component.

While FIG. 1A shows adhesive layer 110 as a discrete segment of tape applied within each pocket 104, other configurations of adhesive layer 110 are contemplated. For example, adhesive layer 110 may include a single adhesive strip applied along the length of the carrier tape. It may be as wide as the width of pocket 104 or it may cover only a portion of the width. It may be as long as the length of pocket 104 or it may cover only a portion of the length. Adhesive layer 110 may include multiple strips of tape spaced from one another. Adhesive layer 110 may also include a ring or bead of adhesive, or a series of spaced dots of adhesive in a circular, triangular, or other shaped distribution. Adhesive layer 110 may be a continuous or non-continuous strip of adhesive screen printed on bottom wall 106 of pocket 104.

The amount, type, and configuration of adhesive layer 110 applied to a carrier tape may vary over a wide range, depending on the size and shape of the component to be secured. In general, neither the shape nor the placement of adhesive layer 110 is crucial, as long as the adhesive has sufficient adhesion to permanently bond components 1000 within pockets 104. Because adhesive layer 110 provides the principle means for retaining components 1000 in pockets 104, a single pocket 104 having a generic design may be used to accommodate various shapes and sizes of components. In other words, pockets 104 need not be closely shaped or sized to receive particular components as long as adhesive layer 110 has the capacity to permanently bond the components to carrier tape 100. The amount of adhesive layer 110 used on carrier tape 100 may vary over a wide range and may be influenced by the size and weight of the component to be permanently bonded in pockets 104 (i.e., larger, heavier components may require more adhesive than smaller, lighter components).

Adhesive layer 110 is selected to be of the type that undergoes a reduction of the adhesive bond strength sufficient to remove component 1000 from pocket 104 when being exposed to UV radiation. In at least one aspect, this facilitates clean removal of component 1000 from adhesive layer 110, such that no adhesive residue remains on the component after it is removed from carrier tape 100. In at least one aspect, it is desired that the adhesive be both non-contaminating and non-corrosive to the components. An exemplary adhesive composition for use in the present invention is a UV radiation curable pressure sensitive adhesive (PSA) material. In at least one embodiment, the adhesive composition includes a hexafunctional aliphatic urethane acrylate oligomer, a pressure sensitive adhesive, a silicone hexa-acrylate material, an inhibitive, a photo initiator, and solvents. In at least one aspect, the hexafunctional aliphatic urethane acrylate oligomer provides extremely fast cure response when exposed to UV or electron beam (EB), which contributes to the speed of component pickup and placement. In at least one aspect, the silicone hexa-acrylate material contributes slip, substrate wetting and flow properties when used as an additive in formulations cured by UV or EB. In at least one aspect, the silicone hexa-acrylate material is used to reduce surface tension after curing, which allows components to be picked up easily without transfer of small molecules of silicon. In at least one aspect, the selection of the photo initiator and the addition of the inhibitor increases the shelf life of the adhesive composition, e.g., to more than one year in a dark environment.

UV radiation may be applied to adhesive layer 110 by a conventional UV light emitting diode (LED) system. Suitable UV LED systems typically includes a power source/control unit, an LED driver module coupled to the power source/control unit, and an LED head with a condenser lens coupled to the LED driver module by an optical cable. The LED head direct the light from the LED light source to a desired location. The flexibility of the optical cable allows a user to freely adjust and fix the LED head with five degree freedom to obtain optimal UV curing efficiency and flexibility. For example, the LED head can be easily installed on an SMT machine to accurately and efficiently apply UV radiation to the adhesive layer. In some UV LED systems, the number of LED driver modules and LED heads can be upgraded to sixteen units allowing for multiple cure areas. A typical UV LED system causes no thermal damage or harmful effects to objects being irradiated, its low power consumption makes it an energy-saving and environmentally friendly light source, the built-in LED has an expected life of 20,000 hours, and no light guides or lamp replacements are required. At least for these reasons, a UV LED system is well-suited for use in SMT applications.

Flexible substrate 102 includes a plurality of advancement structures 112 disposed along a longitudinal edge 102b, 102c of flexible substrate 102 for advancing carrier tape 100. In at least one embodiment, the plurality of advancement structures 112 includes at least one row of aligned advancement holes formed in flexible substrate 102 and extending in a row spaced inwardly from one of the longitudinal edges 102b, 102c. The exemplary embodiment illustrated in FIGS. 1A-1B includes two rows of advancement holes, one row spaced inwardly from longitudinal edge 102b, the other row spaced inwardly from longitudinal edge 102c. Advancement structures 112 are typically sized and spaced to engage with a specific advancement mechanism (not shown). The advancement mechanism may include, for example, one sprocket for each row of advancement holes, where the teeth of each sprocket engage the advancement holes to advance carrier tape 100 toward a predetermined location so that the robotic placement equipment may either place components on the carrier tape or remove components from the carrier tape.

Carrier tape 100 may be formed of any resin material that has a sufficient gauge and flexibility to permit it to be wound about the hub of a storage reel. In addition, the resins that can be used for component carrier tapes of this invention are dimensionally stable, durable, and readily formable into the desired configuration. Suitable resin materials include, but are not limited to, polyesters (e.g., glycol-modified polyethylene terephthalate, or polybutylene terephthalate), polycarbonate, polypropylene, polystyrene, polyvinyl chloride, acrylonitrile-butadiene-styrene, amorphous polyethylene terephthalate, polyamide, polyolefins (e.g. polyethylene, polybutene, or polyisobutene), modified poly(phenylene ether), polyurethane, polydimethylsiloxane, acrylonitrile-butadiene-styrene resins, and polyolefin copolymers. In some embodiments, the material has a melt temperature in the range of 400° F. to 630° F. The carrier tape may be optically clear, pigmented or modified to be electrically dissipative. In the latter case, the carrier tape may include an electrically conductive material, such as carbon black or vanadium pentoxide, either dispersed within the resin material or coated onto the surface(s) of the formed carrier tape. The electrically conductive material helps dissipate an electric discharges that can occur during removal of the cover film or unwinding of the carrier tape assembly from a storage spool thus helping to prevent damage to the electronic components contained within the pockets of the carrier tape. In addition dyes, colorants, pigments, UV stabilizers, or other additives may be added to the resin material before forming the carrier tape. In at least one aspect, the carrier tape material may be selected from a material that is not transparent to UV radiation, for example a material having a transmission to UV radiation that is less than 5% or less than 1%. Alternatively, the carrier tape material may be selected from a material that is transparent to UV radiation.

In at least one embodiment, carrier tape 100 is unitary and may be made by thermoforming structures such as, e.g., walls or pockets, in flexible substrate 102. The particular process used for manufacturing or forming carrier tape 100 is also typically selected to best suit the material and thickness of the material chosen for carrier tape 100. More specifically, a polymeric sheet may be supplied either in roll form, sheet form, by continuous injection molding, or by extrusion. The sheet is conveyed to a heater, where the sheet is heated to permit thermoforming of the sheet. The temperature to which the polymeric sheet is heated may vary widely depending on the gauge of the sheet and the type of material from which the sheet is made. Any structures are then thermoformed by drawing the heated polymeric sheet with a die or dies to form the structures to the desired size and shape. The thermoformed carrier tape is then typically cooled until the polymeric material is sufficiently solidified. The carrier tape may then be subjected to other processing steps, such as punching advancement holes along at least one of the edge surfaces of the tape, to meet particular functional requirements of the tape.

Adhesive layer 110 may be applied to carrier tape 100 during the process of forming carrier tape 100, or may be applied in a later, separate process, as long as that process occurs before components are placed in pockets 104.

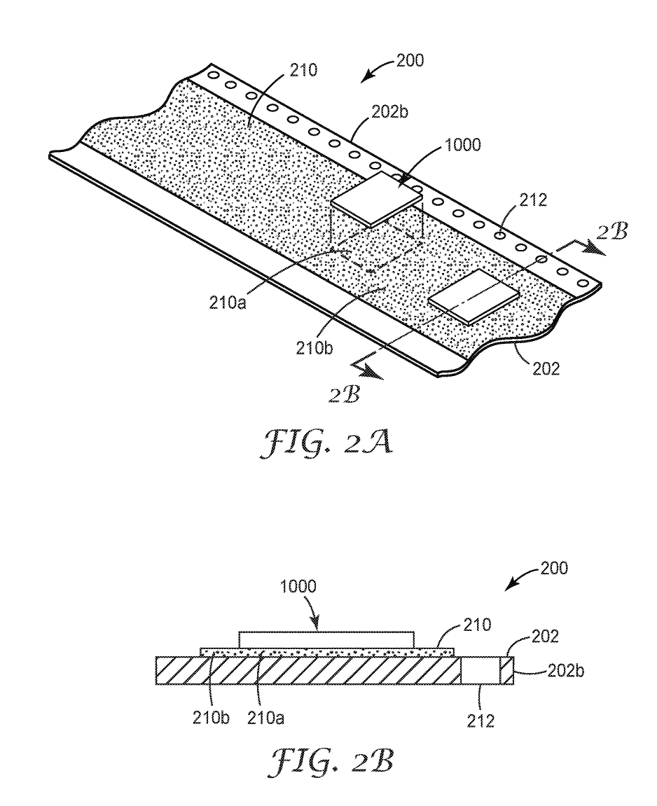

FIGS. 2A-2B illustrate another exemplary embodiment of a component carrier tape according to an aspect of the present invention. Carrier tape 200 is suitable for transporting a plurality of components 1000. Carrier tape 200 includes a flexible substrate 202 extending along a longitudinal axis of carrier tape 200. A continuous component holding layer 210 is disposed on flexible substrate 202. In at least one aspect, the adhesive formulation of continuous component holding layer 210 is similar to the adhesive formulation of adhesive layer 110. Continuous component holding layer 210 includes an adhesive first portion 210a and a non-adhesive second portion 210b. Adhesive first portion 210a functions to secure a component to flexible substrate 202 by adhesively bonding to the component. As best illustrated in FIG. 2A, adhesive first portion 210a has a first perimeter, and non-adhesive second portion 210b has a second perimeter which partially coincides with the first perimeter. In at least one aspect, this arrangement of adhesive first portion 210a and non-adhesive second portion 210b allows a component 1000 to be secured to flexible substrate 202 (facilitated by adhesive first portion 210a) and enables winding and transportation of carrier tape 200 (facilitated by non-adhesive second portion 210b).

In at least one embodiment, continuous component holding layer 210 includes alternating adhesive first portions 210a and non-adhesive second portions 210b along the longitudinal axis of carrier tape 200. The first perimeter of each adhesive first portion 210a partially coincides with the second perimeter of an adjacent non-adhesive second portion 210b.

In at least one aspect, continuous component holding layer 210 is similar to adhesive layer 110; it is selected to be of the type that undergoes a reduction of the adhesive bond strength when being exposed to UV radiation. In at least one aspect, continuous component holding layer 210 is initially entirely adhesive. After placement of component 1000 on continuous component holding layer 210, exposing continuous component holding layer 210 to UV radiation from the top side (i.e., the continuous component holding layer side) of the carrier tape defines adhesive first portion 210a, i.e., the portion blocked from UV radiation by component 1000, and non-adhesive second portion 210b, i.e., the portion exposed to UV radiation. This is an example of an embodiment wherein the first perimeter of adhesive first portion 210a is defined by a projection of component 1000. Adhesive first portion 210a maintains the initial adhesive bond strength, which allows component 1000 to be permanently bonded to carrier tape 200. Non-adhesive second portion 210b undergoes a reduction of the adhesive bond strength, which enables winding and transportation of carrier tape 200. Exposing continuous component holding layer 210 to UV radiation from the bottom side (i.e., the side opposite the continuous component holding layer side) of the carrier tape exposes adhesive first portion 210a to UV radiation. Adhesive first portion 210a undergoes a reduction of the adhesive bond strength sufficient to remove component 1000 from flexible substrate 202. In at least one aspect, this facilitates clean removal of component 1000 from continuous component holding layer 210, such that no adhesive residue remains on the component after it is removed from carrier tape 200. In at least one aspect, to facilitate UV radiation from the bottom side of the carrier tape, the carrier tape is transparent to UV radiation.

In at least one aspect, when the adhesive first portions 210a are exposed to UV radiation the adhesive bond strength is reduced to zero. In at least one aspect, when the adhesive first portions 210a are exposed to UV radiation the adhesive bond strength is sufficiently reduced so that the component can be removed without damage to the component or the carrier tape. Flexible substrate 202 includes a plurality of advancement structures 212 disposed along a longitudinal edge 202b of flexible substrate 202 for advancing carrier tape 200. The exemplary embodiment illustrated in FIGS. 2A-2B includes a single row of advancement holes spaced inwardly from longitudinal edge 202b.

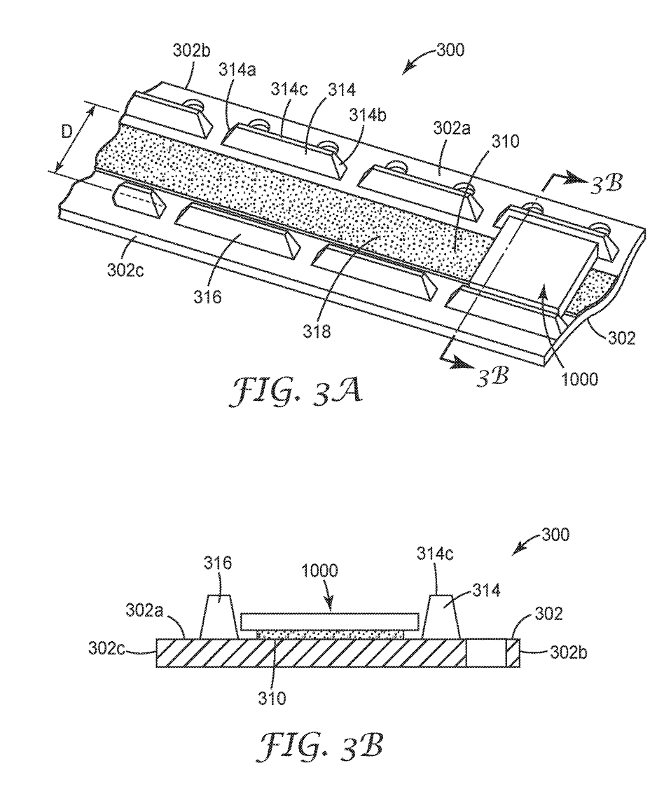

FIGS. 3A-3B illustrate another exemplary embodiment of a component carrier tape according to an aspect of the present invention. Carrier tape 300 is similar to carrier tape 200, but additionally includes a first plurality of longitudinally spaced apart walls 314 and a second plurality of longitudinally spaced apart walls 316. Walls 314 and walls 316 extend upwardly from flexible substrate 302 between first longitudinal edge 302b and second longitudinal edge 302c. Walls 314 extend between walls 316 and first longitudinal edge 302b, and walls 316 extend between walls 314 and second longitudinal edge 302c. In at least one aspect, each wall 314 is spaced an equal distance from first longitudinal edge 302b. However, equal spacing is not required and walls 314 may be staggered. Walls 314 are substantially parallel to first longitudinal edge 302b (i.e., between 0° and 10°) but may be oriented at a larger angle with respect thereto (i.e., greater than 10°). In at least one aspect, each wall 314 is longitudinally spaced an equal distance from each longitudinally adjacent wall. In at least one aspect, each wall 316 is spaced an equal distance from second longitudinal edge 302c. Walls 316 are substantially parallel to second longitudinal edge 302c (i.e., between 0° and 10°). In at least one aspect, each wall 316 is longitudinally spaced an equal distance from each longitudinally adjacent wall. As with walls 314, however, staggered spacing from second longitudinal edge 302c and orientation at a larger angle thereto (i.e., greater than 10°) are possible for walls 316.

Many wall configurations are contemplated by the present invention. For example, walls 314 can have various shapes when viewed in the transverse direction of the carrier tape, such as squares, rectangles, triangles, half circles, and the like. In at least one aspect, the shape of walls 314 is a truncated pyramid, as illustrated in FIGS. 3A-3B. In this embodiment, each wall 314 includes first and second side surfaces 314a and 314b that extend upwardly from flexible substrate 302, and a top surface 314c that connects the side surfaces 314a and 314b at their furthest points from top surface 302a of flexible substrate 302.

In at least one aspect, each wall 314 is adjacent to other walls 314 and each wall 316 is adjacent to other walls 316 in the longitudinal direction of carrier tape 300. In at least one aspect, each wall 314 is positioned so that at least some portion of wall 314 is transversely opposite at least some portion of wall 316. In at least one aspect, each wall 314 is positioned so that at least 95% of wall 314 is transversely opposite at least 95% of wall 316. Pairs of walls 314, 316 are defined as one wall 314 and one wall 316 that are transversely opposite at least some portion of each other. In other words, each one of walls 314 and corresponding one of walls 316 define a pair of walls. The areas or spaces between adjacent pairs of walls 314, 316 have a lower bending moment than the areas where walls 314, 316 extend from flexible substrate 302, which are therefore the preferred areas of flexure for carrier tape 300.

Each wall 314 in a pair of walls 314, 316 is spaced from a wall 316 in that pair of walls by a distance D in the transverse direction of carrier tape 300. The distance D is typically determined by the width of components 1000 that are to be transported on that carrier tape 300.

In at least one aspect, multiple component storage areas 318 are spaced along the length of carrier tape 300, wherein each component storage area 318 is defined between a pair of walls 314, 316. By changing the position, orientation, spacing, and size of walls 314 and 316, component storage areas 318 may be designed to conform to the size and shape of the components they are intended to receive. However, one of the advantages afforded by the present invention is that a single component storage area of generic design can accommodate components of widely varying sizes and shapes. In any case, it is preferred that the height of walls 314 and 316 is greater than the height of the components to provide maximum protection to the components stored in the component storage areas 318.

In at least one aspect, continuous component holding layer 310 is disposed between each pair of walls 314, 316.

Although in at least one embodiment, carrier tape 300 is unitary and may be made by thermoforming walls 314 and 316 in flexible substrate 302, alternatively, carrier tape 300 may be a tape comprised of separate structures attached to top surface 302a of flexible substrate 302. For example, walls 314 and 316 may be attached to the carrier tape by any known attachment method, such as adhesively, or by ultrasonic bonding processes.

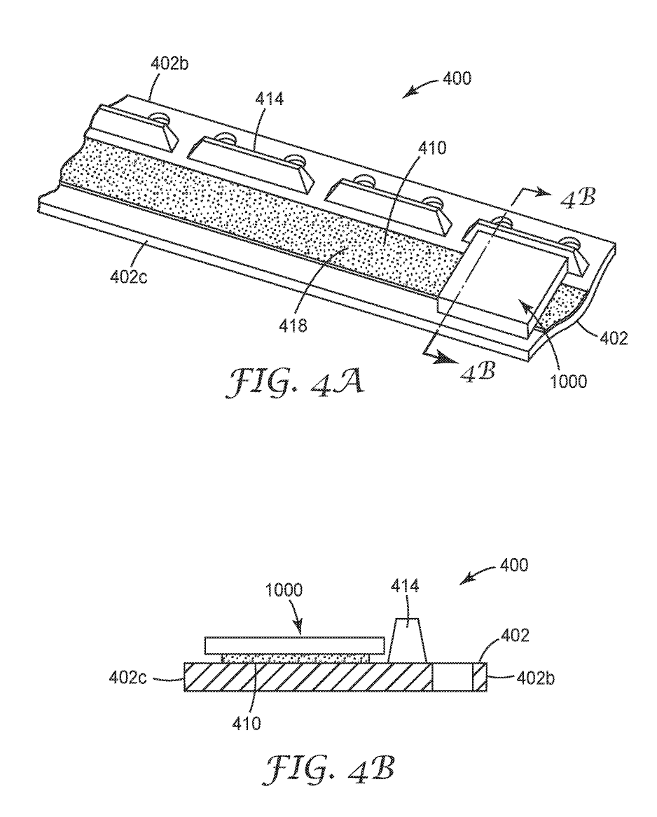

FIGS. 4A-4B illustrate another exemplary embodiment of a component carrier tape according to an aspect of the present invention. Carrier tape 400 is similar to carrier tape 300, but includes only a single plurality of walls 414 spaced inwardly from first longitudinal edge 402b of flexible substrate 402. As a result, continuous component holding layer 410 is disposed between walls 414 and second longitudinal edge 402c. Walls 414 include similar characteristics to walls 314 described above with respect to FIGS. 3A-3B. In this embodiment, there are no walls transversely opposite walls 414. Rather, walls 414 and the area transversely opposite walls 414 define component storage areas 418. In this embodiment, components 1000 are placed on continuous component holding layer 410 adjacent walls 414 so that walls 414 can provide at least partial protection for the components, e.g., when carrier tape 400 is wound about a hub.

In at least one aspect, the advantages of adhesive layers and continuous component holding layers of carrier tapes according to aspects of the present invention with respect to securing and removing components may also apply to securing and removing cover tapes. For example, a permanent bond between a cover tape and a carrier tape facilitates secure storage and transportation of components placed in pockets of the carrier tape and sealed therein by the cover tape. In addition, exposure of the adhesive to UV radiation allows the cover tape to be quickly and easily removed from the carrier tape, after which the components can be removed from the pockets, without the presence of adhesive residue on the carrier tape.

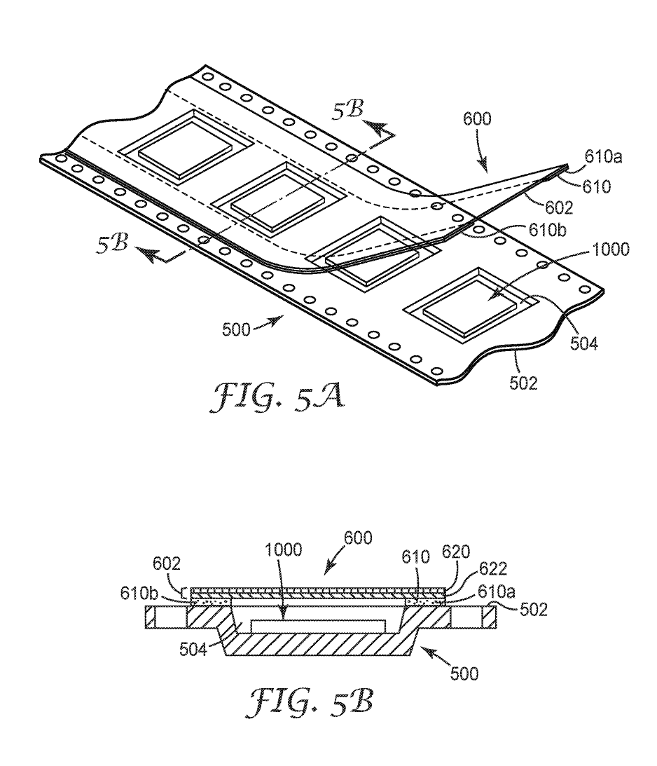

FIGS. 5A-5B illustrate an exemplary embodiment of a component carrier tape and cover tape according to an aspect of the present invention. Carrier tape 500 includes a flexible substrate 502 extending along a longitudinal axis of carrier tape 500. A plurality of pockets 504 is formed in substrate 502. Pockets 504 are spaced apart along the longitudinal axis of carrier tape 500. In at least one embodiment, carrier tape 500 is similar to carrier tape 100, but does not include an adhesive layer disposed in the pockets. The adhesive layer may be omitted, e.g., when components can be properly secured in the pockets by a cover tape. In at least one embodiment, carrier tape 500 is similar to carrier tape 100, and does include an adhesive layer disposed in the pockets. The adhesive layer may be included, e.g., when components cannot be properly secured in the pockets by a cover tape.

Cover tape 600 includes a flexible substrate 602 extending along a longitudinal axis of cover tape 600. Cover tape 600 further includes an adhesive layer 610 disposed on a surface of flexible substrate 602. In at least one aspect, the adhesive formulation of adhesive layer 610 is similar to the adhesive formulation of adhesive layer 110. In at least one aspect, the adhesive formulation contributes to an increased shelf life of the cover tape, e.g., to more than one year in a dark environment. Adhesive layer 610 is disposed on a surface of flexible substrate 602 such that when cover tape 600 is applied to carrier tape 500 that includes a component 1000 placed in a pocket 504 of carrier tape 500, adhesive layer 610 permanently bonds to carrier tape 500 to permanently seal component 1000 in pocket 504. This means that adhesive layer 610 of the cover tape bonds to the carrier tape such that the cover tape cannot be removed from the carrier tape without damage to the carrier tape, the cover tape, or both.

In addition, adhesive layer 610 is disposed on a surface of flexible substrate 602 such that when the adhesive is exposed to UV radiation the adhesive bond strength is sufficiently reduced so that the cover tape can be removed from the carrier tape and the component can be removed from the pocket. In at least one aspect, this method of removing the cover tape from the carrier tape reduces vibrations to the carrier tape during component pickup and placement, which increases the effectiveness (rate) of component pickup and placement. In at least one aspect, when the adhesive is exposed to UV radiation the adhesive bond strength is sufficiently reduced so that the cover tape can be efficiently handled after removal from the carrier tape. For example, when a cover tape collection bin is used to receive the cover tape, any build-up of adhesive residue on the nip rollers and the interior surfaces of the collection bin, preventing proper advancement of the cover tape, is eliminated. As a result, the cover tape can be properly removed without interruption of the pick and place operation.

In at least one aspect, when the adhesive is exposed to UV radiation the adhesive bond strength is reduced to zero. In at least one aspect, when the adhesive is exposed to UV radiation the adhesive bond strength is sufficiently reduced so that the cover tape can be removed without damage to the cover tape or the carrier tape.

In at least one aspect, adhesive layer 610 includes parallel longitudinal bonding portions 610a, 610b disposed adjacent opposing longitudinal edges of flexible substrate 602. Each bonding portion 610a, 610b is configured to bond cover tape 600 to carrier tape 500 at the corresponding longitudinal edge of cover tape 600. Other configurations of adhesive layer 610 may be used as suitable for the intended application.

In at least one aspect, flexible substrate 602 includes a base layer 620 and an antistatic layer 622 disposed on base layer 620. Adhesive layer 610 is disposed on a surface of antistatic layer 622. Base layer 620 provides a major contribution to the overall mechanical strength of the cover tape. Base layer 620 has two generally parallel planar major surfaces. The base layer may be selected from bi-axially stretched polyesters, polyolefins, or nylons. The base layer may include polyethylene terephthalate (PET), bi-axially oriented polypropylene (BOPP), bi-axially oriented polyamide (BOPA), or any other suitable polymeric material. In at least one aspect, the base layer material may be selected from a material that is not transparent to UV radiation, for example a material having a transmission to UV radiation that is less than 5% or less than 1%. Alternatively, the base layer material may be selected from a material that is transparent to UV radiation. The base layer may have a thickness of about 10 microns to about 30 microns or more preferably of about 12 microns to about 20 microns. Additionally, the base layer may have an optical transmittance not less than 85%, and a tensile strength not less than 50 MPa.

Antistatic layer 622 is formed on one of the major surfaces of base layer 620. The base layer may be coated with an antistatic coating which forms the antistatic layer having a dry film thickness of about 0.001 microns to about 0.5 microns and more preferably between 0.01 microns and 0.1 microns. A thicker antistatic layer may create a debris issue when sealing and removing the cover film from a carrier tape while too thin of a layer will not provide adequate antistatic performance. The antistatic layer may have a surface resistivity of about 1×10⁶ ohm/□ to about 1×10¹² ohm/□, preferably between about 1×10⁹ ohm/□ and about 1×10¹² ohm/□. The antistatic coating for the antistatic layer can be coated on base layer 620 by a gravure coating process or other conventional low viscosity coating process. The antistatic coating for the antistatic layer may include a conductive polymer coating such as an addition type cationic antistatic coating or a polymer grafting type cationic antistatic agent coating. Exemplary suitable conductive polymers include, but are not limited to, polyacetylene, polypyrrole, polythiophene, polyaniline, polyether amides-based or polyester amides-based intrinsic antistatic polymers or the like, or combinations thereof. Alternatively, antistatic coating for the antistatic layer may include a conductive filler or salt dispersed in a solvent suspended polymeric binder or bound to a polymeric binder delivered in either a neat form or as a solvent dispersion. Exemplary conductive fillers include metal oxides, carbon nanotubes or other conductive particles. An exemplary conductive salt can be a tetravalent ammonium salt.

Antistatic layer 622 may include carbon nanotubes in a polymeric binder. An aqueous solution of the carbon nanotubes and the polymeric binder may be applied to the surface of the base layer by a gravure roll coating method or other conventional liquid coating method. After drying, the resulting thickness of the antistatic layer can be from about 0.1 microns to about 1 micron, more preferably between about 0.2 microns and about 0.6 microns. The carbon nanotubes composition of the antistatic layer is from about 0.5 wt. % to about 3 wt. % in the polymer binder (i.e. the polymer binder content is from about 97 wt. % to about 99.5 wt. %) based on the total dry coating weight of the antistatic layer.

Antistatic layer 622 contributes to a permanent antistatic performance of the cover tape to help provide electrostatic discharge protection both when the carrier tape is unwound from its carrier spool and when the cover tape is removed from the carrier tape.

In at least one aspect, cover tape 600 is not transparent to UV radiation. For example, cover tape 600 may have a transmission to UV radiation that is less than 5% or less than 1%. When cover tape 600 is not transparent to UV radiation, exposing adhesive layer 610 to UV radiation may occur from the bottom side (i.e., the adhesive layer side) of cover tape 600. In at least one aspect, this type of cover tape is configured to be used with a carrier tape that is transparent to UV radiation, so that adhesive layer 610 can be exposed to UV radiation from the bottom side of cover tape 600 when cover tape 600 is bonded to the carrier tape.

In at least one aspect, cover tape 600 is configured to be used with a carrier tape that is not transparent to UV radiation. For example, the carrier tape may have a transmission to UV radiation that is less than 5% or less than 1%. When the carrier tape is not transparent to UV radiation, exposing adhesive layer 610 to UV radiation may occur from the top side (i.e., the side opposite the adhesive layer side) of cover tape 600. In at least one aspect, this type of cover tape is transparent to UV radiation.

### EXAMPLES

This invention is illustrated by the following examples, but the particular materials and amounts thereof recited in these examples, as well as other conditions and details should not be construed to unduly limit this invention.

### Materials

Hexafunctional aliphatic urethane acrylate oligomer: EBECRYL 1290E, Cytec Industries, Inc., New Jersey, U.S.A.
Pressure sensitive adhesive: 1860Z, Ashland, Inc., Kentucky, U.S.A., 35% solid
Silicone hexa-acrylate material: EBECRYL 1360, Cytec Industries, Inc., New Jersey, U.S.A.
Inhibitive: 4-methoxyphenol
Photo initiator: IRGACURE 184, BASF SE, Ludwigshafen, Germany
Solvent: Ethyl acetate (EA)
Solvent: Methyl ethyl ketone (MEK)

### Equipment:

Mixing: Standard mixer
Vibration testing: Standard vibration tester
Visual examination: Standard microscope at 200× magnification
Exposure to UV radiation: Standard UV LED system

### Example 1

Step 1: An adhesive composition was prepared by mixing predetermined quantities of materials according to Table 1 using the mixer.

TABLE 1

| Material | Quantity |
|---|---|
| EBECRYL 1290E | 32.79 wt % (50 g) |
| 1860Z | 26.23 wt % (40 g) |
| EBECRYL 1360 | 6.56 wt % (10 g) |
| 4-methoxyphenol | 0.07 wt % (0.1 g) |
| IRGACURE 184 | 1.57 wt % (2.4 g) |
| EA | 19.67 wt % (30 g) |
| MEK | 13.11 wt % (20 g) |

Step 2: The adhesive composition was coated onto a substrate such as to form an adhesive layer having a thickness of about 25 μm.

Step 3: The components were bonded to the adhesive layer and subjected to 0.1 million round vibration testing using the vibration tester. A visual examination confirmed that the components had not moved relative to the adhesive layer.

Step 4: The adhesive layer was exposed to UV radiation provided by the UV LED system for about 1 second, after which the components could be removed immediately. A visual examination confirmed that no adhesive residue remained on the components.

Unless otherwise indicated, all numbers expressing quantities, measurement of properties, and so forth used in the specification and claims are to be understood as being modified by the term “about”. Accordingly, unless indicated to the contrary, the numerical parameters set forth in the specification and claims are approximations that can vary depending on the desired properties sought to be obtained by those skilled in the art utilizing the teachings of the present application. Not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, to the extent any numerical values are set forth in specific examples described herein, they are reported as precisely as reasonably possible. Any numerical value, however, may well contain errors associated with testing or measurement limitations.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the mechanical and materials arts will readily appreciate that the present invention may be implemented in a very wide variety of embodiments. This application is intended to cover any adaptations or variations of the preferred embodiments discussed herein. Therefore, it is manifestly intended that this invention be limited only by the claims and the equivalents thereof.

What is claimed is:

1. A carrier tape for transporting a plurality of components, comprising:
a flexible substrate extending along a longitudinal axis of the carrier tape; and
a continuous component holding layer disposed on the flexible substrate and comprising:
an adhesive first portion for securing a component to the flexible substrate by adhesively bonding to the component, the adhesive first portion having a first perimeter; and
a non-adhesive second portion having a second perimeter partially coinciding with the first perimeter.

2. The carrier tape of claim 1, wherein the continuous component holding layer comprises alternating adhesive first portions and non-adhesive second portions along the longitudinal axis of the carrier tape, the first perimeter of each adhesive first portion partially coinciding with the second perimeter of an adjacent non-adhesive second portion.

3. The carrier tape of claim 1, wherein when the adhesive first portions are exposed to UV radiation the adhesive bond strength is sufficiently reduced so that the component can be removed from the flexible substrate.

4. The carrier tape of claim 3, wherein when the adhesive first portions are exposed to UV radiation the adhesive bond strength is reduced to zero.

5. The carrier tape of claim 3, wherein when the adhesive first portions are exposed to UV radiation the adhesive bond strength is sufficiently reduced so that the component can be removed without damage to the component or the carrier tape.

6. The carrier tape of claim 1, wherein the flexible substrate includes first and second longitudinal edges, the carrier tape further comprising a first plurality of longitudinally spaced apart walls extending upwardly from the flexible substrate between the first and second longitudinal edges.

7. The carrier tape of claim 6, wherein the continuous component holding layer is disposed between the first plurality of walls and the second longitudinal edge.

8. The carrier tape of claim 6 further comprising a second plurality of longitudinally spaced apart walls extending upwardly from the flexible substrate between the first plurality of walls and the second longitudinal edge, each one of the first plurality of walls and corresponding one of the second plurality of walls defining a pair of walls.

9. The carrier tape of claim 8, wherein the continuous component holding layer is disposed between each pair of walls.
